(19) United States
(12) Patent Application Publication
(10) Pub. No.: US 2025/0068529 A1
(43) Pub. Date: Feb. 27, 2025

(54) TEST AND REPAIR ARCHITECTURE FOR INTER AND INTRA CLUSTER DEFECTS

(71) Applicant: Intel Corporation, Santa Clara, CA (US)

(72) Inventor: Sreejit CHAKRAVARTY, San Jose, CA (US)

(21) Appl. No.: 18/236,821

(22) Filed: Aug. 22, 2023

(51) Int. Cl. G06F 11/22

(52) U.S. Cl. CPC G06F 11/2242

(57) ABSTRACT

Embodiments disclosed herein include apparatuses for improved testing between chips. In an embodiment, an apparatus comprises a plurality of transmit clusters on a first chip, where individual ones of the plurality of transmit clusters comprise a set of transmit lanes on the first chip. In an embodiment, a plurality of finite state machines (FSMs) are on the first chip, where individual ones of the plurality of transmit clusters comprise one of the plurality of FSMs. In an embodiment, a global transmit test generator is communicatively coupled to each of the set of transmit lanes on the first chip, and a global transmit expected response generator is communicatively coupled to each of the plurality of FSMs on the first chip.

### BACKGROUND

Various benefits including reduced power consumption and reduced form factor size can be achieved by integrating multiple semiconductor dies into a single package. The individual die are sometimes referred to as chiplets or compute tiles. For example, a processor can be built with compute tiles stacked vertically or side-by-side. However, various challenges are presented in testing such devices to ensure proper operation.

Testing can be executed at various stages of assembly or fabrication. Sort testing refers to the testing of a single die before assembly. In some instances, this can be done prior to singulation of individual dies. Class testing refers to testing interconnects between two dies that have been coupled together, for example through the use of micro bumps or the like. As such, the individual dies may have testing architectures suitable for both sort testing and die testing.

Typically, the testing is carried out at a cluster level. The cluster may include a set of interconnects, bumps, traces, etc. that are physically located proximate to each other. The testing process proceeds with testing each lane in the cluster, and then moving on to the next cluster. Such testing architectures allow for the detection of intra cluster defects. That is, defects that reside entirely within a given cluster can be detected. However, inter cluster defects (i.e., defects that span between two clusters) are not detectable using such testing architectures.

### BRIEF DESCRIPTION OF THE DRAWINGS

FIG. 1 is an example arrangement of transmit and receive clusters of signal paths between dies, in accordance with an embodiment.

FIG. 2A depicts an example of signal paths between a transmit cluster in a transmit (Tx) die and a receive cluster in a receive (Rx) die, in accordance with an embodiment.

FIG. 2B depicts another view of the signal path, between a Tx die and an Rx die, in accordance with an embodiment.

FIG. 2C depicts a view of signal paths with a redundant clock path, in accordance with an embodiment.

FIG. 3 depicts an example of micro bump interconnects between a Tx die and an Rx die, in accordance with an embodiment.

FIG. 4 depicts an example of paths between Tx and Rx functions of adjacent dies, in accordance with an embodiment.

FIG. 5 depicts an example of paths between Tx and Rx functions of adjacent dies and non-adjacent dies, in accordance with an embodiment.

FIG. 6 depicts an example of a logical view of interconnect components between dies, in accordance with an embodiment.

FIGS. 7A-7D depict examples of different defects involving micro bumps, in accordance with an embodiment.

FIG. 8 depicts examples of periodic signals applied to a transmit or receive lane under test, in accordance with an embodiment.

FIG. 9A depicts clusters of a first die and a second die, in accordance with an embodiment.

FIG. 9B depicts clusters of a first die and a second die with inter cluster and intra cluster defects, in accordance with an embodiment.

FIG. 10A depicts an example of an interconnect architecture for a cluster, in accordance with an embodiment.

FIG. 10B depicts an example of an interconnect architecture for a pair of clusters, in accordance with an embodiment.

FIG. 10C depicts an example of an interconnect architecture with global test generators and global expected response generators serving a plurality of clusters, in accordance with an embodiment.

FIG. 11 depicts an example configuration of finite state machines (FSMs), in accordance with an embodiment.

FIG. 12 depicts an example configuration of a clocking structure, in accordance with an embodiment.

FIG. 13 depicts a flowchart of an example process for performing sort testing of chip Tx clusters, in accordance with an embodiment.

FIG. 14 depicts a flowchart of an example process for performing sort testing of chip Rx clusters, in accordance with an embodiment.

FIG. 15 depicts a flowchart of an example process for performing class testing of first chip Tx clusters and second chip Rx clusters, in accordance with an embodiment.

FIG. 16 illustrates an electronic system that includes dies that are coupled together and include testing architectures, in accordance with an embodiment.

FIG. 17 is a schematic of a computing device built in accordance with an embodiment.

### EMBODIMENTS OF THE PRESENT DISCLOSURE

Described herein are electronic systems, and more particularly, test and repair architectures for use in testing dies and interconnects between dies, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, testing and repair architectures are used to improve the yield of dies and of multi-die modules where multiple dies are coupled together. The testing is commonly done at a cluster level. A cluster refers to a set of interconnects, signal propagation lanes (or traces), and the like that are physically located proximate to each other. Typically, a cluster will include either transmit (Tx) lanes or receive (Rx) lanes. However, existing solutions are limited in their ability to test for defects between clusters. So called inter cluster defects may occur when an interconnect proximate to the edge of the cluster forms a defect with an interconnect proximate to the edge of an adjacent cluster.

Existing solutions are limited to finding intra cluster defects due to limits in the testing architecture. For example, each cluster may include a finite state machine (FSM) to run the test. Each FSM is includes a test signal generator and an expected response generator. Further, the testing is done one lane at a time and one cluster at a time. As such, interactions between clusters cannot be observed.

Accordingly, embodiments disclosed herein include a testing and repair architecture that is configured to provide inter cluster defect detection. Generally, embodiments disclosed herein use a global test signal generator and a global expected response generator. This allows for multiple clusters to be tested in parallel with each other. Since clusters are tested at the same time, issues with inter cluster defects can be detected because neighboring clusters are tested together.

Embodiments disclosed herein enable both sort testing and class testing. As such, dies are able to be tested (and repaired) at different stages of assembly. This can lead to improved high volume manufacturing (HVM) yield and improved profitability. The repair of defective lanes can be cured through the use of redundant lanes within a cluster. When one signaling lane is found to be defective, embodiments may include reassigning that defective signal to one of the redundant lanes.

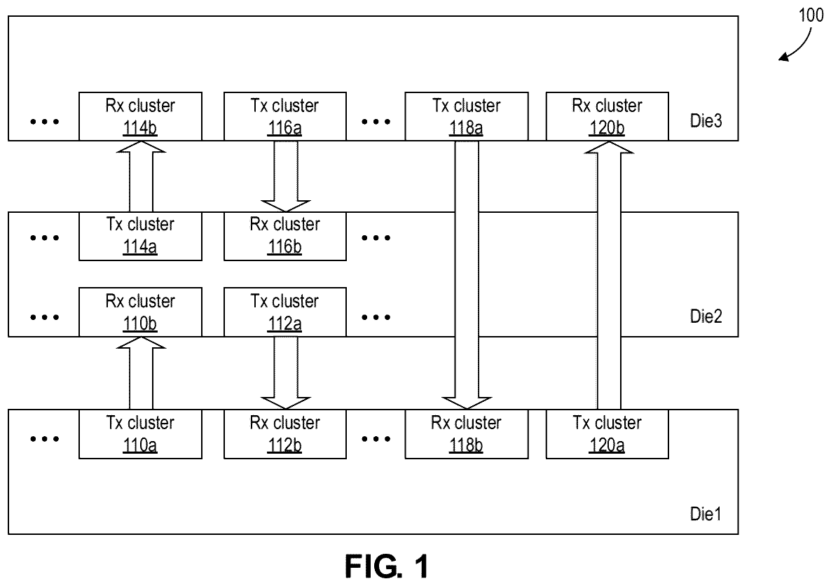

FIG. 1 depicts an example arrangement of transmit and receive clusters of signal paths between chips, in accordance with various embodiments. An example multi-die package 100 includes three chips or die: Die1, Die2 and Die3. The die may be arranged vertically, one atop the other, for example. In some cases, a lower die, or base die, includes input/output (I/O), memory and other logic functions and a higher die is a computer die which can include a processor core and graphics processors. Moreover, the different die may be built and developed using different technologies.

In another option, the die are arranged laterally on a substrate, side by side rather than vertically on top of one another. However, the techniques provided herein are particularly suitable for vertically arranged die due to the greater density of interconnects and the types of defects which occur especially in the vertical configuration.

During packaging, interconnects between Die1 and Die2, Die2 and Die3, and Die1 and Die3 may be formed to create the complete packaged product. Many unidirectional signals run between pairs of die. For each signal, there is a transmit (Tx) end in one die and a receive (Rx) end in another die. Moreover, while designing these interconnects, the large number of signals are divided into clusters. A Tx cluster on one die transmits signals to a corresponding Rx cluster on another die. Cluster sizes of 36, 48 and 64 signals can be used, for instance. Moreover, there could be multiple clock lanes in a cluster if clock repair is implemented.

For example, a Tx cluster 110a on Die1 transmits signals to an Rx cluster 110b on Die2. A cluster can refer to a set of paths and associated circuitry for communicating on the paths. A Tx cluster 112a on Die2 transmits signals to an Rx cluster 112b on Die1. A Tx cluster 114a on Die2 transmits signals to an Rx cluster 114b on Die3. A Tx cluster 116a on Die3 transmits signals to an Rx cluster 116b on Die2. In the above examples, the communicating die are adjacent to one another. In another example, the communicating die are non-adjacent and are separated by one or more intermediate die. For example, a Tx cluster 118a on Die3 transmits signals to an Rx cluster 118b on Die1 via Die2, and a Tx cluster 120a on Die1 transmits signals to an Rx cluster 120b on Die3 via Die2.

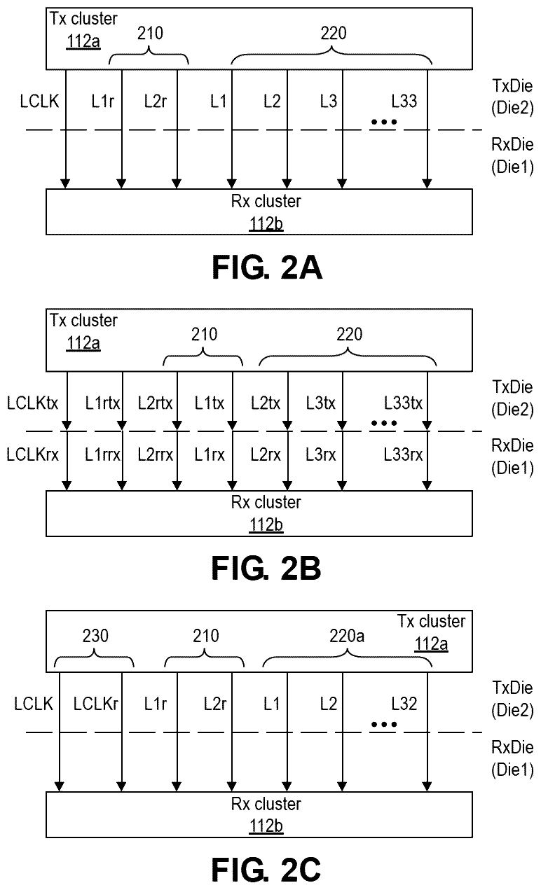

FIG. 2A depicts an example of signal paths between a transmit cluster in a transmit (Tx) die and a receive cluster in a receive (Rx) die, in accordance with various embodiments. Each cluster includes a set of transmit or receive paths or lanes for communicating functional signals between dies. Each cluster can also include one or more redundant lanes, and a clock lane. The number of functional signals can vary. The Tx cluster 112a and Rx cluster 112b of FIG. 1 are depicted as an example. As mentioned, a cluster can have 36, 48 or 64 lanes, for instance. For example, there are 36 lanes here. LCLK is a lane used for a clock signal, L1r and L2r are redundant lanes in a set 210 of one or more redundant lanes, and L1-L33 are normal lanes in a set of normal lanes 220. A normal lane is a default lane in which a signal is carried in the absence of a defect. A redundant lane can be assigned as a replacement lane for a default lane which is found to be defective/faulty.

FIG. 2B depicts another view of the signal paths of FIG. 2A, in accordance with various embodiments. Each path or lane can include a portion in the Tx cluster 112a and a corresponding portion in the Rx cluster 112b. For example, LCLK includes LCLKtx in the Tx cluster 112a and LCLKrx in the Rx cluster 112b. L1r includes L1rtx in the Tx cluster 112a and L1rrx in the Rx cluster 112b. L2r includes L2rtx in the Tx cluster 112a and L2rrx in the Rx cluster 112b. L1-L33 include L1tx-L33tx, respectively, in the Tx cluster 112a and L1rx-L33rx, respectively, in the Rx cluster 112b.

FIG. 2C depicts another example of signal paths between a transmit cluster 112a in a transmit (Tx) die and a receive cluster 112b in a receive (Rx) die, consistent with FIG. 1, where two clock lanes LCLK and LCLKr are provided, in accordance with various embodiments. In this case, two of the 36 lanes are used for a clock signal. In particular, a set 230 of clock lanes include a first, normal or default clock lane LCLK and a second redundant clock lane LCLKr. A common clock signal is provided on both clock lanes, and the clock signal on LCLKr can be used as a replacement for the clock signal on LCLK if testing indicates LCLK is defective. This approach is different than the use of the redundant lanes since the clock signal is provided on both clock lanes even when there is no defect. This avoids the complexity of assigning a replacement lane for the clock signal and ensures that the clock signal is constantly available.

The redundant lanes L1r and L2r for functional signals between the dies are provided as before, along with lanes L1-L32 in a set 220a of lanes, where 32 default lanes instead of 33 are available due to the use of the extra clock lane.

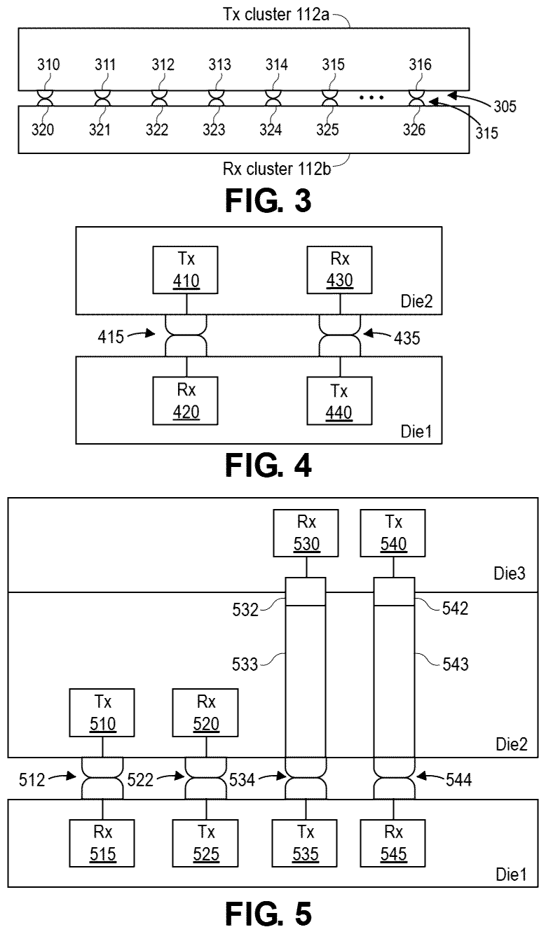

FIG. 3 depicts an example of micro bump interconnects of the Tx and Rx dies, in accordance with various embodiments. The Tx cluster 112a and the Rx cluster 112b each include a set of micro bumps corresponding to the number of lanes. The micro bumps are depicted as being in a single row in this simplified example but in practice could be arranged in multiple rows in a two-dimensional grid on a top or bottom surface of a chip. For example, the Tx cluster 112a includes a set 305 of micro bumps 310-316 and the Rx cluster 112b includes a set 315 of micro bumps 320-326 which are connected to, e.g., touching, micro bumps 310-316, respectively. In one possible implementation, copper micro bumps are spaced apart at a 40 μm pitch, with a 20-25 μm bump size and a spacing of 15 μm spacing between adjacent bumps on the die. Though, other bump sizes and pitches may also be used. The micro bumps can be used to connect the metal layers in two adjacent dies.

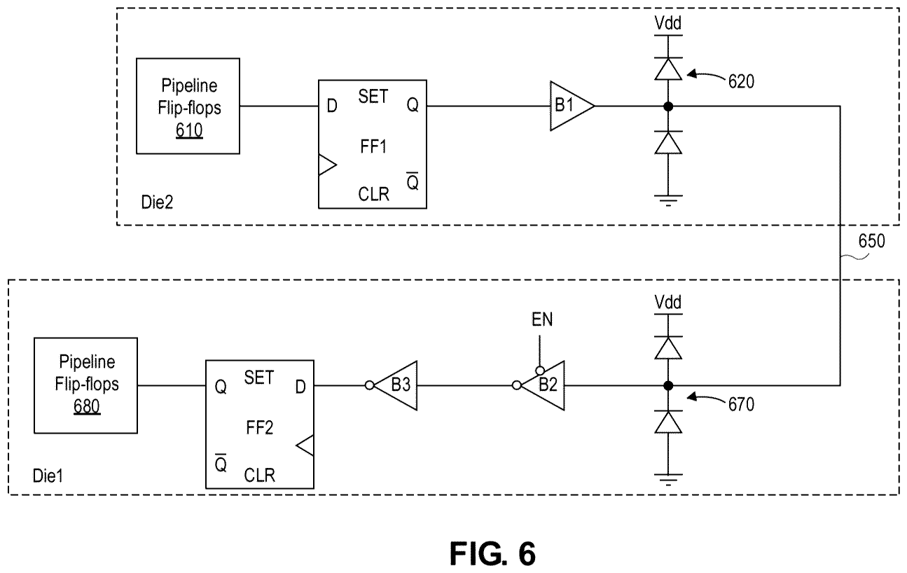

FIG. 4 depicts an example of paths between Tx and Rx functions of adjacent dies, in accordance with various embodiments. Each micro bump provides an interconnect to the adjacent die, where the interconnect can be modelled as a pair of Tx and Rx circuits and the associated pair of micro bumps. For example, a Tx circuit 410 in Die2 can transmit signals to an Rx circuit 420 in Die1 via a pair of micro bumps 415. A Tx circuit 440 in Die1 can transmit signals to an Rx circuit 430 in Die2 via a pair of micro bumps 435.

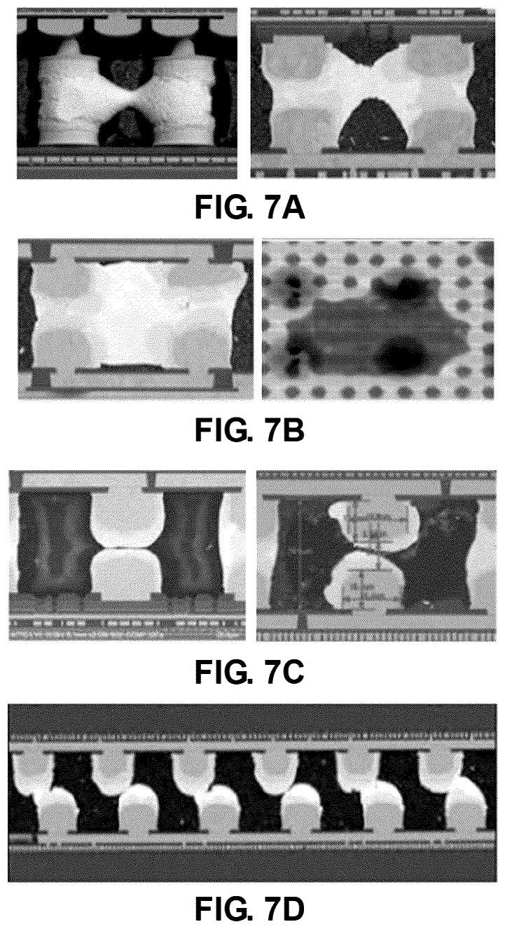

FIG. 5 depicts an example of paths between Tx and Rx functions of adjacent dies and non-adjacent dies, in accordance with various embodiments. In this example, Die1 and Die2 are adjacent, and Die2 and Die3 are adjacent. Additionally, the interconnects for Die1 and Die2 are micro bumps while the interconnects between Die2 and Die3 are hybrid bonding interconnects (HBI). As mentioned, micro bumps can be spaced apart at a 40 μm pitch, for example, where this pitch can be potentially scaled down to 20 μM or 10 μm. HBIs are a type of interconnect which can be used with pitches of 10 μm and lower. HBIs connect dies in packages using tiny copper-to-copper connections, as opposed to bumps, to provide a greater interconnect density.

An HBI can refer to a permanent bond that combines a dielectric bond with embedded metal to form an interconnect. It is sometimes referred to as a direct bond interconnect. In some cases, the HBI includes adhesives. In other cases, the HBI includes various interconnect metals such as copper (Cu), indium (In), and silver (Ag). One example is solid-liquid inter-diffusion (SLID). Another example is a binary bonding approach that uses InAg combined with atmospheric plasma surface activation.

In this example, Die2 is an intermediate die located above Die1 and below Die3. A Tx circuit 510 in Die2 can transmit signals to an Rx circuit 515 in Die1 via a pair of micro bumps 512. A Tx circuit 525 in Die1 can transmit signals to an Rx circuit 520 in Die2 via a pair of micro bumps 522. A Tx circuit 535 in Die1 can transmit signals to an Rx circuit 530 in Die3 via a pair of micro bumps 534, a through-silicon via 533 (TSV) and an HBI 532. A TSV or through-chip via is a vertical electrical connection (via) that passes completely through a silicon wafer or die. TSVs are high-performance interconnect techniques which provide higher density and shorter connections. Similarly, a Tx circuit 540 in Die3 can transmit signals to an Rx circuit 545 in Die1 via an HBI 542, a through-silicon via 543 (TSV) and a pair of micro bumps 544.

The concepts depicted could extend to more than three dies as well. For example, a bottom die, Die1, could transmit signals to a fourth die which is above Die3 using TSVs in Die2 and Die3.

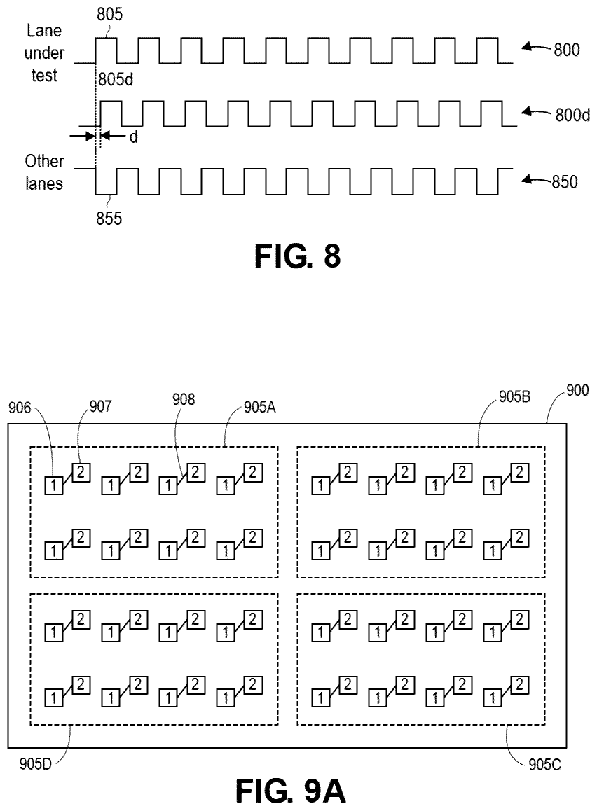

FIG. 6 depicts an example of a logical view of interconnect components, in accordance with various embodiments. This example represents a transmission path from Die2 to Die1. In Die2, a pipeline of flip-flops 610 provides data to a flip-flop FF1. The pipeline receives data from a controller, processor or other control circuit.

FF1 may be an inverting flip flop, also referred to as a D flip flop. FF1 includes a SET input, a CLR (clear) input, a data (D) input and a CLK (clock) input, represented by a triangle, indicating that the flip-flop is edge-triggered. The outputs include Q and Q̅, the inverse of Q. In this type of flip-flop, when CLK increases, Q is reset to 0 if D=Q=0, or Q is set to 1 if D=Q=1. When CLK decreases, there is no change in Q or Q̅. Data output from the Q output is provided to a buffer B1 and then to Die1 via an interconnect 650. The interconnect 650 can represent a pair of micro bumps or HBI, for example. A pair of diodes 620 is provided in Die2 for electrostatic discharge protection (ESD). One diode is connected to a power supply Vdd and the other diode is connected to ground.

The data is received in Die1 via the interconnect 650. Die1 also has a pair of diodes 670 for ESD. The data is provided to a tri-state buffer B2. A tri-state buffer has three possible output states: high (1), low (0) and floating. The tri-state buffer has an input A, an output Y and an enable control line E. When the enable input is true, the tri-state buffer acts as a simple buffer, transferring the input value to the output. The tri-state buffer may be an active-low inverting tri-state buffer, in one approach. In this approach, the output is enabled or disabled when a logic level “0” is applied to the enable control line. When the enable signal is a low level or 0, the buffer is enabled and the output is the complement or inverse of the input. When the enable signal is a high level or 1, the buffer is disabled and the output is at a high impedance condition. The tri-state buffer can therefore act as a switch by either passing or blocking the inverse of the input data based on whether the switch is turned on or off, respectively. Having an active low buffer is helpful as it reduces the power used for the enable control line.

After the input data is inverted at the tri-state buffer B2, it is inverted again to its original state on the interconnect 650 by an inverting buffer B3. The data is then provided to a flip-flop FF2 which operates similarly to FF1. Data output from the Q output is provided to a pipeline of flip-flops 680 for further processing by a controller, processor or other control circuit.

The transmitting die, Die2, could also include buffers such as B2 and B3 after the diode 620 to disconnect the transmit lanes from the micro bumps or other interconnect in a sort test of Die2. In another approach, the transmitting die but not the receiving die includes the buffers B2 and B3. A common enable signal can be used for each of the tri-state buffers in a cluster, in one approach.

As described further below, in one aspect, a die can be subject to a test by itself in a sort test, typically before the die is connected to another die. In another aspect, a pair of die can be subject to a class test when they are coupled together directly or indirectly via one or more other die. The sort test may be performed on many die in a wafer, before wafer slicing. Class testing occurs after a die is connected to other die in a multi-die package. In the sort test, the tri-state buffer is disabled since there is no interconnect between die and the testing is performed within a single die. In the class test, the tri-state buffer is enabled since there is an interconnect between die and the testing requires transmission between two dies.

The interconnect components shown are associated with a single lane in a set of lanes such as depicted in FIGS. 2A and 2B. The interconnect components can be provided for each lane in a set of lanes.

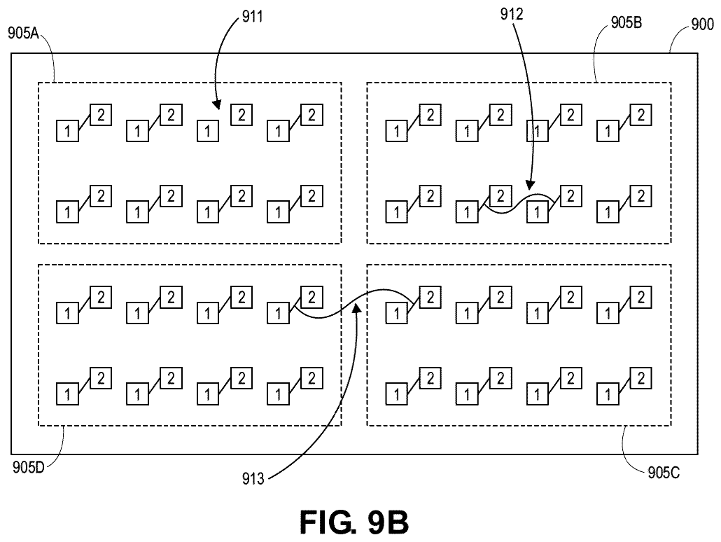

FIG. 7A depicts an example of a first type of defect involving micro bumps, referred to as isolated solder bump bridging. As mentioned, various type of interconnect manufacturing defects are often observed in silicon. The solutions described herein can be better understood in view of these failure mechanisms. Solder bump bridging results in a short circuit between two adjacent interconnects. Two redundant lanes can be used to replace the two short-circuited lanes.

To test for such defects, including those in FIG. 7A-7D, random pattern tests generated by linear feedback shift registers (LFSRs) are not adequate. Instead, single line stress tests, described further below, can be used. Single line stress tests include several phases, where each transmit or receive lane is tested separately, one at a time. In a first phase, a first lane is set to be the target or victim while all other lanes are aggressor lanes. In a second phase, a second lane is set to be the target or victim while all other lanes are aggressor lanes, and so forth. Single line stress tests can be used both for testing and identifying failing lanes. Further, embodiments disclosed herein include testing multiple clusters in parallel in order to detect inter-cluster defects. That is, a lane under test can be provided in multiple different clusters at the same time. A redundant lane can be used to replace each lane which is found to be defective.

FIG. 7B depicts an example of a second type of defect involving micro bumps, referred to as massive solder bump bridging (MSBB). Here, more than two lanes are short circuited together due to a defect. For such defects also, single line stress tests are effective. To repair a short circuit between three lanes, for example, three redundant lanes are required. A multiplexing structure can be provided to perform the repair by routing signals which were intended to travel over a defective path to a replacement path. Generally, the number of such defects which can be repaired is limited to avoid excessive complexity in the multiplexing structure.

FIG. 7C depicts an example of a third type of defect involving micro bumps, referred to as foreign material/non-contact opens. In this case, a foreign material, or a gap, may be present between the two micro bumps which prevents them from contacting one another. Single line stress tests can also be used to detect such defects. Moreover, when the defect involves only one pair of micro bumps, only one redundant lane is required to repair the defect.

FIG. 7D depicts an example of a fourth type of defect involving micro bumps, referred to as die to wafer XY misalignment. In this case, pairs of micro bumps which are intended to contact one another are shifted laterally, e.g., in an x-y direction, where z is a vertical direction, such that the intended contact is not made. This type of defect tends to affect all of the micro bumps in a cluster such that the defect cannot be repaired. Single line stress tests can detect such defects.

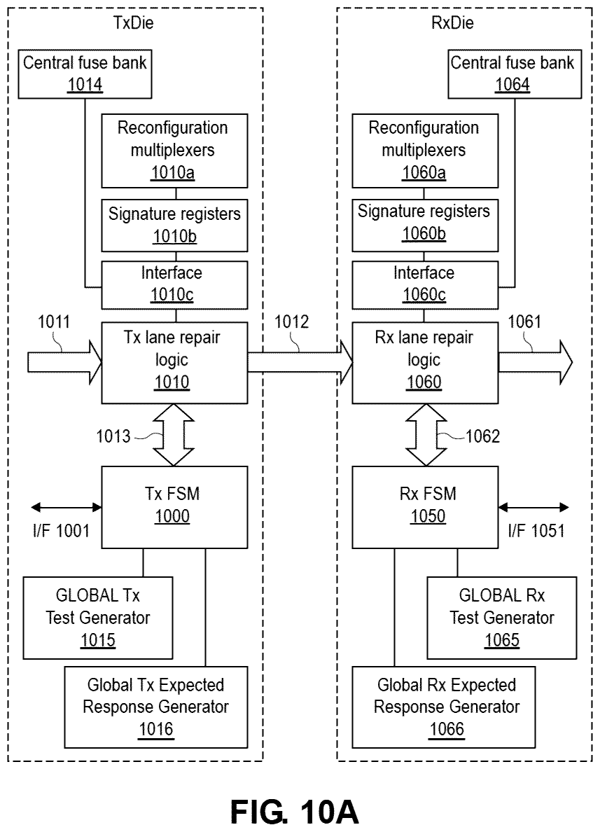

FIG. 8 depicts examples of periodic signals applied to a transmit or receive lane under test, in accordance with various embodiments. As mentioned, to test for defects in the lanes of a cluster, a single line stress test can be performed for each lane, one lane at a time. In one approach, a periodic signal 800 is applied to the lane under test, e.g., the lane currently selected to be tested for a defect, while an opposite-phase periodic signal 850 is applied to the remaining lanes in the cluster. The phase of the periodic signal 850 is shifted 180 degrees, e.g., +/− a threshold such as 10-20 degrees, from the phase of the periodic signal 800. Thus, a peak amplitude in the periodic signal 850 occurs during a minimum amplitude of the period signal 850. The opposite-phase waves tend to capacitively couple to the lane under test. This provides a stress on the lane under test which can modify the signal on the lane under test. If the lane under test is free of defects, the modification of the signal will be relatively small such that a detected signal of the lane under test is as expected, e.g., substantially the same as the periodic signal applied to the lane under test but with an expected shift in time due to the propagation time of the signal.

For example, the signal 800d represents a time-shifted version of the signal 800, where the shift is a time period or delay d. This delay corresponds to a difference between the rise times of the pulse 805 and 805d, for example. A comparator can be used to detect this signal on the lane under test and to determine whether the detected signal is a time-shifted version of a periodic signal which is applied to the lane under test. For example this may require determining that the delay is equal to an expected delay d +/− a threshold error. The time-shifted version of a periodic signal which is applied to the lane under test is an example of an expected response on the lane under test.

The period signals can be a square wave, as depicted, or a sine wave, for example. In this example, the signal 800 is a square wave with a first pulse 805 and the signal 850 is a square wave with first pulse 855. The first pulse 805 has a high amplitude while the time-aligned first pulse 855 has a low amplitude.

As mentioned, in a single line stress test, each transmit or receive lane is tested separately, one at a time. In a first phase, a first lane is set to be the target or victim while all other lanes are aggressor lanes. In a second phase, a second lane is set to be the target or victim while all other lanes are aggressor lanes, and so forth. Thus, in each test, the signal 800 can be applied to the lane under test while the signal 850 is applied to the other, remaining lanes in a cluster. The testing can be performed on a cluster basis to identify defective lanes in a cluster and replace them with replacement lanes. Further, the testing can be performed on multiple clusters in parallel in order to identify inter cluster defects and replace them with replacement lanes. Advantageously, the two periodic signals can be used to detect different types of defects including those depicted in FIG. 7A-7D. This reduces complexity compared to having defect-specific test signals.

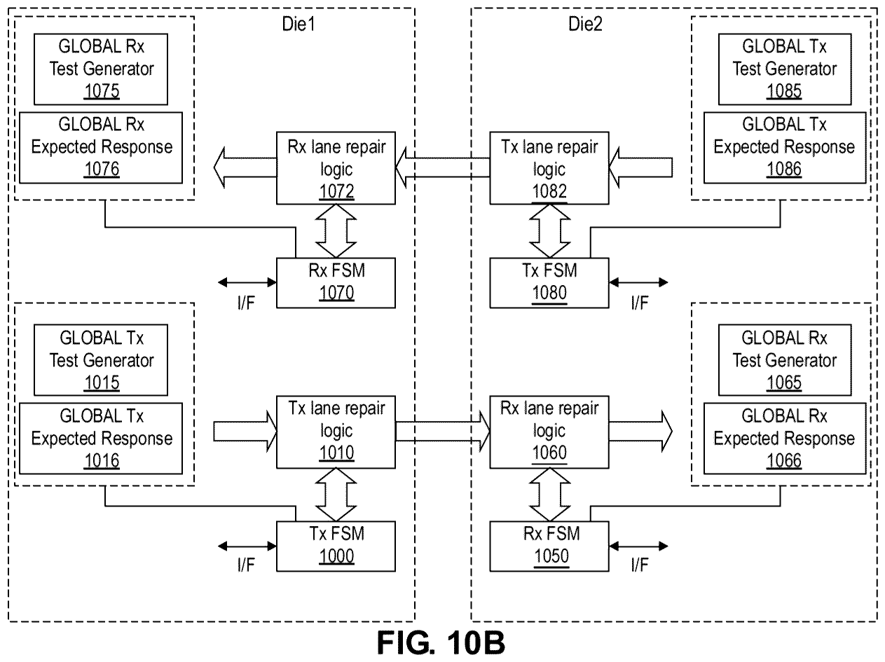

FIG. 9A illustrates a stack 900 of dies. The stack 900 includes a plurality of clusters. For example, clusters 905A, 905B, 905C, and 905D are shown. Each cluster 905 may correspond to a Tx cluster on one die and an Rx cluster on the other die. That is, stack 900 may include dies that communicate with each other. As shown, lanes 906 are on the first die (as represented by the numeral 1), and lanes 907 are on the second die (as represented by the numeral 2). An interconnect 908 is provided between corresponding lanes 906 and 907. The interconnect 908 may be a micro bump, an HBI, or the like. More particularly, the lanes 906 and 907 may be provided directly over each other, despite being shown as having an offset in FIG. 9A. In the embodiment shown in FIG. 9A, all of the interconnects 908 are functional. That is, there are no defects in FIG. 9A.

FIG. 9B illustrates a stack 900 of dies that does have defects. Various different defect types may be included in the stack 900. For example, defect 911 may be a non-contact open, and defect 912 may be an example of solder bump bridging. Both defects 911 and 912 may be referred to as intra cluster defects since they both occur entirely within a single cluster (i.e., defect 911 is in cluster 905A, and defect 912 is in cluster 905B).

However, inter cluster defects may also arise. For example, defect 913 is an example of an inter cluster defect. As shown, interconnects 908 are bridged across the boundary of cluster 905C and the boundary of cluster 905D. Such an inter cluster defect may not be detectable using existing test and repair architectures. Accordingly, embodiments allow for parallel testing of the clusters 905 in order to detect such inter cluster defects.

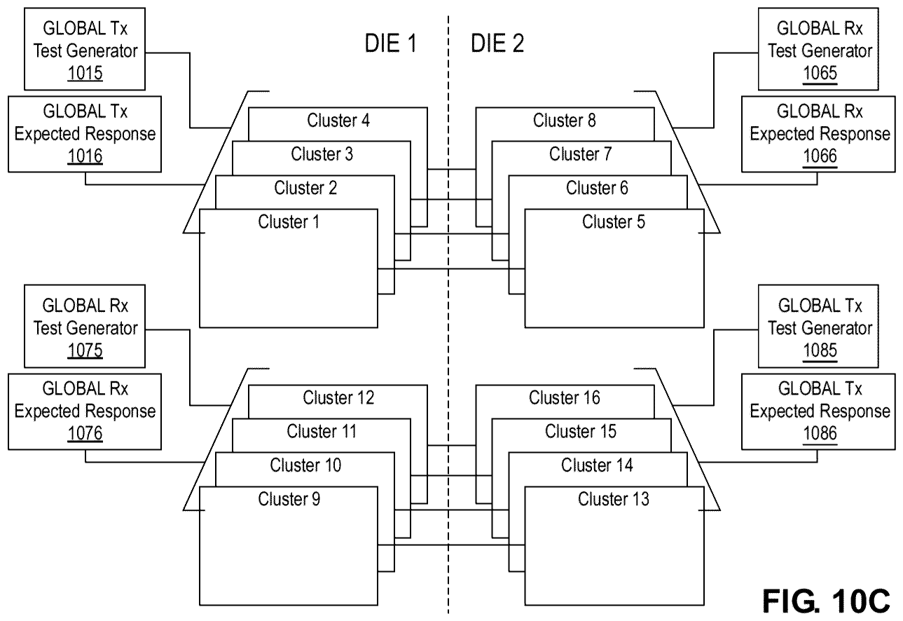

FIG. 10A depicts an example of an interconnect architecture for a cluster, in accordance with various embodiments. The architecture may be provided for each cluster, in one approach, except that a central fuse bank may be shared among multiple clusters in a die, in one approach. In this architecture, one die is the transmitting die (TxDie), e.g., the die transmitting a signal, and the other die is the receiving die (RxDie), e.g., the die receiving a signal. Generally, the architecture includes built-in self-test (BIST) components at the Tx and Rx dies. The Tx die includes the Tx end lanes through which functional signals are propagated. It also contains the redundant lanes, repair reconfiguration multiplexers 1010a, signature registers 1010b, and an interface 1010c to a central fuse bank 1014, such as an electrical fuse bank. The Tx die also contains the Tx FSM 1000 which generates the test stimuli, analyzes the response, and identifies the failing lane based on which it calculates the repair signature. Similarly, the Rx die contains lanes, including the redundant lanes, carrying the functional signals, repair configuration multiplexers 1060a, signature registers 1060b, and an interface 1060c, to a central fuse bank 1064 on the Rx die. The Rx die also contains the Rx FSM 1050 which can generate the test stimuli, analyze the response, and identify the failing lane.

In particular, the TxDie includes Tx lane repair logic 1010 and a Tx FSM 1000. The Tx lane repair logic 1010 receives data on an input path 1011, e.g., from a controller, processor or other control circuit, and outputs the data on an interconnect path 1012. The input path and output path may represent the normal or default lanes in a cluster, for example. The Tx lane repair logic 1010 may include reconfiguration multiplexers 1010a which route an incoming signal to a redundant lane when the lane which would normally carry the signal is found to be defective. For example, in FIG. 2A, if L2 is defective, the signal which would normally be carried by L2 may be routed to L1r, the first redundant lane. The reconfiguration multiplexers 1010a can be configured based on reconfiguration information read into signature registers 1010b from a central fuse bank 1014 via an interface 1010c. This can be done at the time of powering up the TxDie, for example. The fuses comprise non-volatile memory so that the reconfiguration information can be permanently stored for the lifetime of a die.

The reconfiguration information can be obtained by the Tx FSM 1000 during testing of the lanes of the Tx Die. The Tx lane repair logic 1010 may communicate with the Tx FSM 1000 via an interface 1013.

The Tx FSM 1000 in turn may communicate with a controller, processor or other control circuit via an interface (I/F) 1001 such as one using the IEEE-P1687 Internal Joint Test Action Group (iJTAG) standard, titled “IEEE P1687 Standard for Access and Control of Instrumentation Embedded within a Semiconductor Device.” This is a standard interface to control configurations within the state machine and read out the contents of the state machine.

In an embodiment, the Tx FSM 1000 may further be communicatively coupled to a global Tx test generator 1015 and a global Tx expected response generator 1016. The global generators 1015 and 1016 may be shared across multiple clusters within the Tx Die. This enables parallel testing of the clusters in order to detect inter cluster defects, such as those described in greater detail above.

The RxDie includes Rx lane repair logic 1060 and an Rx FSM 1050. The Rx lane repair logic 1060 receives signals on the interconnect path 1012 and outputs corresponding signals on an output path 1061, e.g., to a controller, processor or other control circuit. The Rx lane repair logic 1060 may include reconfiguration multiplexers 1060a which route an incoming signal on a redundant lane to a lane which would normally carry the signal. For example, in FIG. 2A, if a signal which would normally be carried on L2 in TxDie is received on L1r, the signal may be routed back to L2 in RxDie. The reconfiguration multiplexers 1060a can be configured based on reconfiguration information read into signature registers 1060b from a central fuse bank 1064 via an interface 1060c. This can be done at the time of powering up the RxDie, for example.

The Rx lane repair logic 1060 may communicate with the Rx FSM 1050 via an interface 1062. The Rx FSM 1050 in turn may communicate with a controller, processor or other control circuit via an interface (I/F) 1051.

In an embodiment, the Rx FSM 1050 may further be communicatively coupled to a global Rx test generator 1065 and a global Rx expected response generator 1066. The global generators 1065 and 1066 may be shared across multiple clusters within the Rx Die. This enables parallel testing of the clusters in order to detect inter cluster defects, such as those described in greater detail above.

FIG. 10B depicts an example of an interconnect architecture for a pair of clusters, in accordance with various embodiments. This example includes the Tx FSM 1000, Tx lane repair logic 1010 on TxDie, Rx FSM 1050 and Rx lane repair logic 1060 on RxDie of FIG. 10A, in connection with a first cluster of lanes such as the lanes associated with the Tx cluster 110a and Rx cluster 110b of FIG. 1. The example further includes components associated with an additional cluster on the same die. This includes a Tx FSM 1080 and Tx lane repair logic 1082 on Die2, and an Rx FSM 1070 and Rx lane repair logic 1072 on Die1, in connection with a second cluster of lanes such as the lanes associated with the Tx cluster 112a and Rx cluster 112b of FIG. 1. Providing a separate FSM and testing of each cluster helps reduce complexity and reduce test time since different clusters can be tested concurrently.

Additionally, the FSMs 1000, 1050, 1070, and 1080 may be communicatively coupled to global generators. For example, each FSM may be coupled to a global test generator and a global expected response generator. Global Tx test generator 1015 and global Tx expected response generator 1016 are coupled to Tx FSM 1000 on Die1, global Rx test generator 1075 and global Rx expected response generator 1076 are coupled to Rx FSM 1070 on Die1, global Tx test generator 1085 and global Tx expected result generator 1086 are coupled to Tx FSM 1080 on Die2, and global Rx test generator 1065 and global Rx expected response generator 1066 are coupled to Rx FSM 1050 on Die 2.

FIG. 10C is an illustration of a Die1 and Die2 that illustrates a plurality of clusters. For example, clusters 1-4 may be Tx clusters on Die1 and clusters 5-8 may be Rx clusters on Die2 that are coupled to clusters 1-4, respectively. Similarly, clusters 9-12 may be Rx clusters on Die1 and clusters 13-16 may be Tx clusters on Die2 that are coupled to clusters 9-12, respectively. As illustrated, each grouping of clusters may be serviced by global generators. For example, clusters 1-4 are communicatively coupled to global Tx test generator 1015 and global Tx expected response generator 1016, and clusters 5-8 are communicatively coupled to global Rx test generator 1065 and global Rx expected response generator 1066. Similarly, clusters 9-12 are communicatively coupled to global Rx test generator 1075 and global Rx expected response generator 1076, and clusters 13-16 are communicatively coupled to global Tx test generator 1085 and global Tx expected response generator 1086.

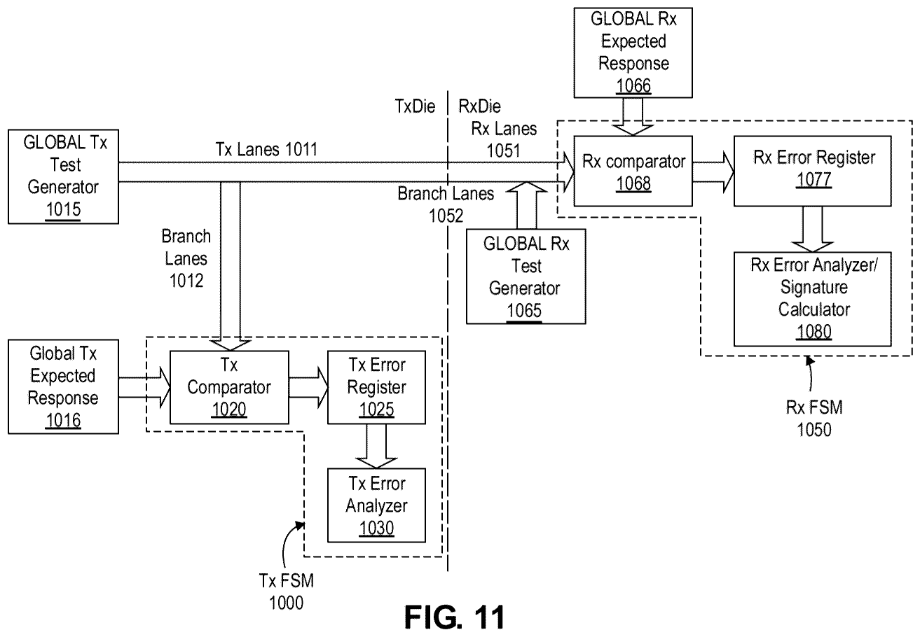

FIG. 11 depicts an example configuration of the FSMs 1000 and 1050 of FIG. 10A, in accordance with various embodiments. Both the TxDie and the RxDie can include: (i) a test stimulus/signal generator; (ii) an expected response generator; (iii) a comparator comparing the expected response with the observed response; (iv) error register, one per lane; and (v) an error analyzer which calculates the repair signature, if repair is possible. A repair is generally possible when the number of redundant lanes is adequate to substitute for the defective lanes. The stimulus generator can be, e.g., a linear feedback shift register (LFSR) or a single line stress test stimulus generator. The expected response mirrors the stimulus generated by the stimulus generator.

Not all components shown are used simultaneously. As shown, for sort testing, where only a single die is tested in a standalone mode, all the components shown on the die are used. For class testing, where testing is done post-packaging, the test generator at the Tx die and the expected response generator and comparator at the Rx die are used. In this case, the Rx die calculates the repair signature, a copy of which is then moved to the Tx die. A repair signature can identify a defective lane and a corresponding replacement lane.

In an example implementation, during a test for defects in a cluster, a global Tx signal generator 1015 transmits or applies periodic test signals on Tx lanes 1011, such as depicted in FIG. 8. If the Tx die alone is being tested, in a sort test, the Tx lanes 1011 are not connected to the Rx lanes 1051 of the RxDie. Instead, the test signals are carried on branch lanes 1012 to the Tx FSM 1000. The Tx FSM 1000 may include a Tx comparator 1020. For the lane under test, the Tx comparator 1020 detects a signal on the lane under test and compares it to an expected response as provided by a global Tx expected response generator 1016. For example, the Tx comparator 1020 can compare an amplitude and/or phase of the detected signal to an expected amplitude and/or phase. For instance, the timing of low-to-high transitions and/or high-to-low transitions in the detected signal can be compared to expected timings. If the timing differs from the expected timing by more than a specified amount, the lane under test is considered to be defective. Other factors such as the number of clock pulses in the detected signal can be compared with an expected number of clock pulses in a time period. If there is a defect/error in a lane under test, a Tx error register 1025 stores the identity of the lane and a Tx error analyzer 1030 calculates the repair signature, if repair is possible.

As indicated with the prefix “global”, the global Tx test generator 1015 and the global Tx expected response generator 1016 can be shared with other clusters (not shown). As such, multiple clusters may be tested in parallel in order to determine if there are any inter cluster defects, such as those described above.

If the Tx die is being tested in connection with the Rx die, in a class test, the Tx lanes 1011 are connected to the Rx lanes 1051 of the RxDie. The tri-state buffers B2 (FIG. 6) or other switches in line with the Rx lanes can be provided in a turned on or conductive state in this case to allow the received test signals to reach an Rx comparator 1068 of the Rx FSM 1050. For the lane under test, the Rx comparator 1068 detects a signal on the lane under test and compares it to an expected response as provided by a global Rx expected response generator 1066, similar to the way the Tx comparator works. If there is a defect/error in a lane under test, an Rx error register 1077 stores the identity of the lane and an Rx error analyzer 1080 calculates the repair signature, if repair is possible.

If the Rx die is being tested alone, in a sort test, a global Rx signal generator 1065 transmits or applies periodic test signals on the Rx lanes 1051 via branch lanes 1052. The tri-state buffers B2 (FIG. 6) or other switches in line with the Rx lanes can be turned off in this case to disconnect the Rx lanes from the micro bumps or other interconnect of the RxDie. The test signals are provided to the Rx comparator 1068 of the Rx FSM 1050 for analysis as discussed.

Test signals transmitted between the dies, from the TxDie to the RxDie, can be the same as, or different than, the test signals transmitted only within a die in a sort test, in one approach. Also, a test signal transmitted within a Tx die in a sort test can be the same as, or different than, a test signal transmitted within an Rx die in a sort test.

In a sort test, the techniques disclosed herein provide failure analysis using die isolation. A tri-state buffer or other switch on the Tx or Rx die can be used to isolate the die when the die is connected to another die. System test support is also provided. A signal (e.g., FBIST_SYSTEST_START) is provided to the Tx FSM 1000 and the Rx FSM 1050 from a controller, processor other control circuit, to trigger the execution of a BIST on each die. The two die can be tested concurrently, for example. The FSM on the Tx die generates a test pattern, and the FSM on the Rx die reports the pass/fail status of the test. A signal (FBIST_SYSTEST_FAIL) can be generated for each cluster. These signals from all the clusters can be aggregated to indicate, at the system level, the pass/fail status of the test. As described above, multiple clusters can be tested in parallel using global signal generators in order to determine inter cluster defects as well.

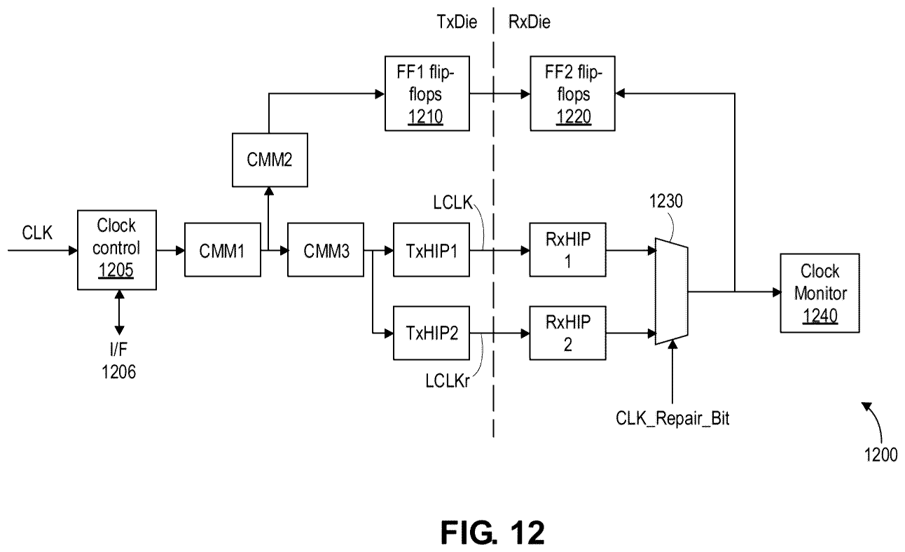

FIG. 12 depicts an example configuration of a clocking structure 1200, in accordance with various embodiments. As indicated in connection with FIG. 2C, a clock signal can be provided concurrently on both a normal or default clock lane and on an extra clock lane for use in case the normal, default clock lane is found to be defective during testing. This feature thus involves clock test and repair support where one or more redundant lanes are provided for a clock signal which is transmitted between dies. An example BIST clocking structure is provided. The structure includes a clock control circuit 1205 which receives a clock signal CLK. The clock signal CLK may be a global clock signal CLK that is provided to a plurality of different clusters. The clock control circuit 1205 may provide a corresponding output to a first clock modifier module (CMM1). CMM1 in turn provides an output to a second clock modifier module (CMM2). CMM2 in turn provides an output to the FF1 flip-flops 1210. The FF1 flip-flops 1210 represent a bank or set of the FF1 flip-flops such as shown in FIG. 6, one for each lane in a cluster of the TxDie. Under the control of the clock signal, the FF1 flip-flops provide data via die-to-die interconnects to the FF2 flip-flops 1220 in the RxDie. The FF2 flip-flops 1220 represent a bank or set of the FF2 flip-flops such as shown in FIG. 6, one for each lane in a cluster of the RxDie.

CMM2 also provides an output to a third clock modifier module (CMM3). CMM3 in turn provides an output to TxHIP1 and TxHIP2. TxHIP1 and TxHIP2 are components of the Tx die which include the buffer B1 and the ESD diode 620 of FIG. 6. TxHIP1 and TxHIP2 are coupled to the two clock lanes, LCLK and LCLKr, which are added to the inter-die connections. If LCLK is functioning, then the clock propagated along that lane is used. Otherwise, if LCLK is not functioning, e.g., has a short circuit, open circuit or other defect, then the same clock propagated along LCLKr is used. LCLK and LCLKr are coupled to RxHIP1 and RxHIP2, respectively. RxHIP1 and RxHIP2 are components of the Rx die which include the buffers B2 and B3 and the ESD diode 670 of FIG. 6.

The clock lane to be used by a clock monitor 1240 is selected by a multiplexer 1230 based on an input signal. At the Tx die, the clock control circuit 1205 controls the clock burst used for testing the interconnects, where the number of clock cycles is programmable through an interface (I/F) 1206 such as iJTAG. At the Rx die, the clock monitor 1240 counts the number of clock cycles. To test the clock path, the clock control circuit can be set to send out a pre-determined number of clock pulses. The clock monitor counts the number of clock pulses received, where the observed clock count observed determines the quality of the clock lane. The clock monitor can then select the clock signal on LCLK if that clock signal has a good quality, e.g., is not defective, or the clock signal on LCLKr if the clock signal on LCLK is defective.

Moreover, at the Tx die, the programmable clock modifier modules CMM1-CMM3 can be used to: (i) move the clock edge; and (ii) modify the duty cycle. These clock modifiers are used to: (i) measure and tune the skew between the data and the clock, at both the Tx and Rx die; and (ii) compensate for discrepancies in silicon in the clock network between the two die.

Thus, the clocking structure can be used to determine if a lane, e.g., LCLK, for transmitting a clock signal between die has a defect. If the lane has a defect, a copy of the clock signal on another lane, e.g., LCLKr, is used to provide the clock signal to the RxDie. The two (or more) lanes LCLK and LCLKr can be added to the lanes of a cluster shown in FIG. 2C, for example.

In an example implementation, an apparatus includes first and second clock lanes to carry a clock signal; a clock monitor to determine whether the clock signal on the first clock lane is defective; and a multiplexer, responsive to the clock monitor, to select the clock signal on the first clock lane if the clock signal on the first clock lane is not defective, and the clock signal on the second clock lane if the clock signal on the first clock lane is defective.

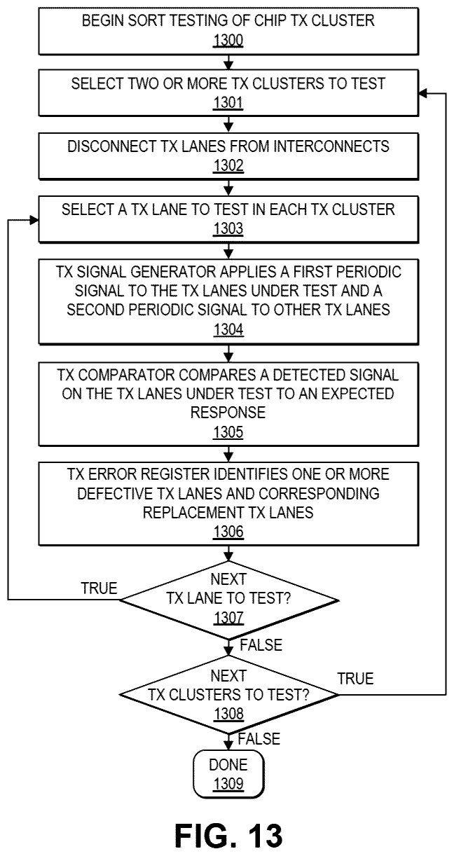

FIG. 13 depicts a flowchart of an example process for performing sort testing of a chip Tx cluster, in accordance with various embodiments. Step 1300 begins sort testing of a chip Tx cluster. Step 1301 includes selecting two or more Tx clusters to test, e.g., among multiple Tx clusters on the chip. Step 1302 includes disconnecting the Tx lanes from the interconnect, e.g., using a tri-state buffer as discussed previously in connection with FIG. 6, if such a buffer is provided for the Tx cluster. Step 1303 includes selecting a Tx lane to test in each Tx cluster, e.g., among multiple Tx lanes of each of the selected Tx clusters. Step 1304 includes using a global Tx signal generator coupled to the two or more clusters to apply a first periodic signal (e.g., signal 800 in FIG. 8) to the Tx lanes under test and a second periodic signal (e.g., signal 850 in FIG. 8) to other Tx lanes.

At step 1305, a Tx comparator in each Tx cluster compares a detected signal on the Tx lanes under test to an expected response from a global expected response generator coupled to each of the selected clusters. At step 1306, a Tx error register in each Tx cluster identifies one or more defective Tx lanes and corresponding replacement Tx lanes. A decision step 1307 then determines whether there is a next Tx lane in the clusters to test. If the decision step 1307 is true (T), step 1303 is repeated. If the decision step 1307 is false (F), a decision step 1308 determines whether there are next Tx clusters on the die to test. If the decision step 1308 is true, step 1301 is repeated. If the decision step 1308 is false, the process is done at step 1309.

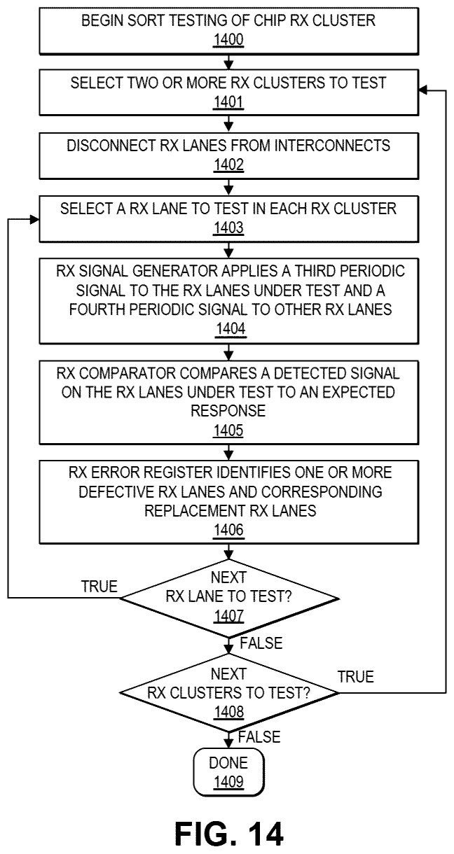

FIG. 14 depicts a flowchart of an example process for performing sort testing of a chip Rx cluster, in accordance with various embodiments. Step 1400 begins sort testing of a chip Rx cluster. Step 1401 includes selecting two or more Rx clusters to test, e.g., among multiple Rx clusters on the chip. Step 1402 includes disconnecting the Rx lanes from the interconnect, e.g., using a tri-state buffer as discussed previously in connection with FIG. 6, if such a buffer is provided for the Rx cluster. Step 1403 includes selecting an Rx lane to test in each cluster, e.g., among multiple Rx lanes of each cluster. Step 1404 includes using a global Rx signal generator coupled to each of the selected clusters to apply a third periodic signal (e.g., signal 800 in FIG. 8) to the Rx lanes under test and a fourth periodic signal (e.g., signal 850 in FIG. 8) to other Rx lanes.

At step 1405, an Rx comparator of each cluster compares a detected signal on the Rx lane under test to an expected response from a global expected response generator coupled to each of the selected clusters. At step 1406, an Rx error register in each cluster identifies one or more defective Rx lanes and corresponding replacement Rx lanes. A decision step 1407 then determines whether there is a next Rx lane in each of the clusters to test. If the decision step 1407 is true (T), step 1403 is repeated. If the decision step 1407 is false (F), a decision step 1408 determines whether there are next Rx clusters on the die to test. If the decision step 1408 is true, step 1401 is repeated. If the decision step 1408 is false, the process is done at step 1409.

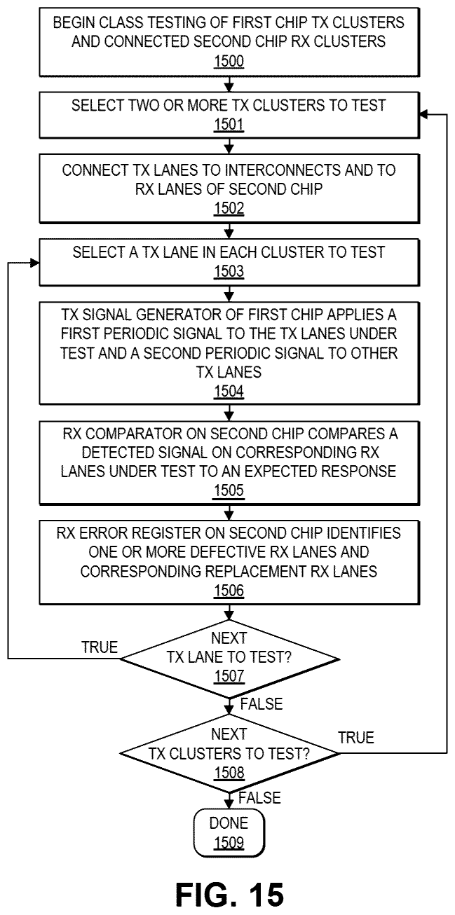

FIG. 15 depicts a flowchart of an example process for performing class testing of first chip Tx clusters and second chip Rx clusters, in accordance with various embodiments. Step 1500 includes beginning class testing of the first chip Tx clusters and their connected second chip Rx clusters, e.g., such as the Tx cluster 110a and the Rx cluster 110b, respectively, of FIG. 1. Step 1501 includes selecting two or more Tx clusters to test. Step 1502 includes connecting the Tx lanes to the interconnects and to the Rx lanes of the second chip. The interconnects could be micro bumps or hybrid bonding interconnects, for example. The connection can involve enabling a tri-state buffer or other switch, for example.

Step 1503 includes selecting a Tx lane to test for each cluster. Step 1504 includes using a global Tx signal generator of the first chip to apply a first periodic signal to the Tx lanes under test and a second periodic signal to other Tx lanes. At step 1505, an Rx comparator for each cluster on the second chip compares a detected signal on a corresponding Rx lane under test to an expected response from a global expected response generator coupled to each of the selected Rx clusters. At step 1506, an Rx error register in each cluster on the second chip identifies one or more defective Rx lanes and corresponding replacement Rx lanes. A decision step 1507 then determines whether there is a next Tx lane in the clusters of the first chip to test. If the decision step 1507 is true (T), step 1503 is repeated. If the decision step 1507 is false (F), a decision step 1508 determines whether there are next Tx clusters on the first chip to test. If the decision step 1508 is true, step 1501 is repeated. If the decision step 1508 is false, the process is done at step 1509.

In one approach, the process can first involve resetting the Tx and Rx die using a common controller, processor or other control circuit (e.g., common to both die under test). The Rx die is then instructed to wait for signals from the Tx die, and the Tx die is instructed to start the test. It is a deterministic test so, after a certain time period, it will terminate. After it is completed, the common controller, processor or other control circuit reads out the signature registers from the Rx die. The test does not require a higher level communication path between the Tx die and Rx die. Moreover, the testing can be done during manufacturing using external automated test equipment (ATE). Information can be read out from each die independently through a test access port (TAP) or JTAG test interface.

Note that a lane can be found to be defective in one test, e.g., a class test, but not in a sort test. The repair signature for a cluster can account for both types of tests to replace a lane which is found to be defective in any of the tests. In one approach, an error analyzer is coupled to a comparator in a FSM in a first chip, and the error analyzer is to provide a repair signature which identifies one or more replacement lanes for one or more defective lanes in response to a test of each lane of the set of lanes which does not involve a second chip, e.g., a sort test of the first chip, and in response to a test of each lane of the set of lanes which does involve the second chip, e.g., a class test of the first chip.

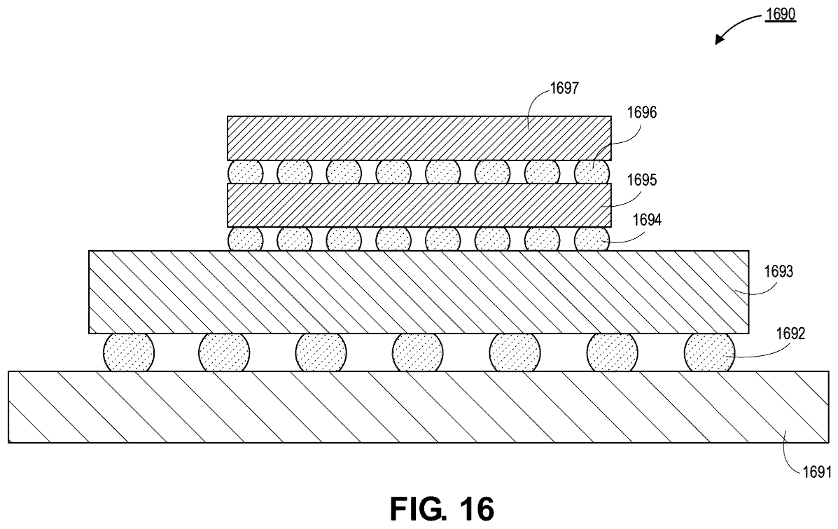

FIG. 16 is a cross-sectional illustration of an electronic system 1690. In an embodiment, the electronic system 1690 may include a board 1691, such as a printed circuit board (PCB) or the like. A package substrate 1693 may be coupled to the board 1691 by interconnects 1692, such as solder balls, sockets, or the like. In an embodiment, two or more dies 1695 and 1697 are coupled to the package substrate 1693 by interconnects 1694, such as any first level interconnect (FLI) architecture. The dies 1695 and 1697 are communicatively coupled together by interconnects 1696, such as micro bumps, HBIs, or the like. In an embodiment, the dies 1695 and 1697 may include Tx clusters and Rx clusters for providing communication between the two dies 1695 and 1697. The clusters may include test and repair functionality, such as test and repair functionality described in greater detail herein. For example, the test and repair functionality may include global test signal generators and global expected signal generators in order to provide parallel testing of clusters in order to detect inter cluster defects. In an embodiment the communication circuitry of the dies 1695 and 1697 may be testable in either a sort test or a class test.

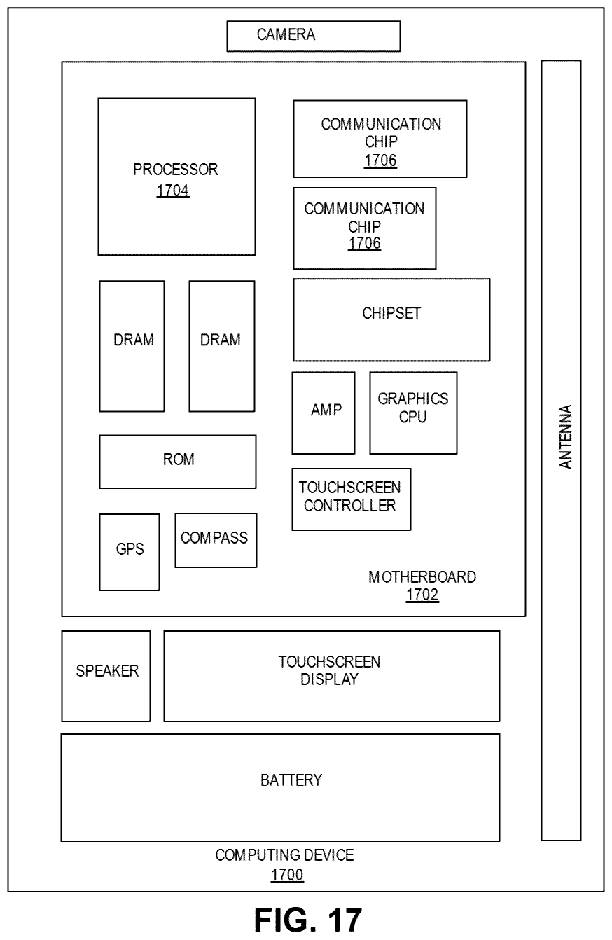

FIG. 17 illustrates a computing device 1700 in accordance with one implementation of the disclosure. The computing device 1700 houses a board 1702. The board 1702 may include a number of components, including but not limited to a processor 1704 and at least one communication chip 1706. The processor 1704 is physically and electrically coupled to the board 1702. In some implementations the at least one communication chip 1706 is also physically and electrically coupled to the board 1702. In further implementations, the communication chip 1706 is part of the processor 1704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1706 enables wireless communications for the transfer of data to and from the computing device 1700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1700 may include a plurality of communication chips 1706. For instance, a first communication chip 1706 may be dedicated to shorter range wireless communications such as Wi-Fi and Bluetooth and a second communication chip 1706 may be dedicated to longer range wireless communications such as GPS, EDGE, GPRS, CDMA, WiMAX, LTE, Ev-DO, and others.

The processor 1704 of the computing device 1700 includes an integrated circuit die packaged within the processor 1704. In some implementations of the disclosure, the integrated circuit die of the processor may be part of an electronic package with two or more dies that have Tx and Rx clusters that are electrically coupled to test and repair circuits with a global test signal generator and a global expected error generator, in accordance with embodiments described herein. The term “processor” may refer to any device or portion of a device that processes electronic data from registers and/or memory to transform that electronic data into other electronic data that may be stored in registers and/or memory.

The communication chip 1706 also includes an integrated circuit die packaged within the communication chip 1706. In accordance with another implementation of the disclosure, the integrated circuit die of the communication chip may be part of electronic package with two or more dies that have Tx and Rx clusters that are electrically coupled to test and repair circuits with a global test signal generator and a global expected error generator, in accordance with embodiments described herein.

In an embodiment, the computing device 1700 may be part of any apparatus. For example, the computing device may be part of a personal computer, a server, a mobile device, a tablet, an automobile, or the like. That is, the computing device 1700 is not limited to being used for any particular type of system, and the computing device 1700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a plurality of transmit clusters on a first chip, wherein individual ones of the plurality of transmit clusters comprise a set of transmit lanes on the first chip; a plurality of finite state machines (FSMs) on the first chip, wherein individual ones of the plurality of transmit clusters comprise one of the plurality of FSMs; a global transmit test generator communicatively coupled to each of the set of transmit lanes on the first chip; and a global transmit expected response generator communicatively coupled to each of the plurality of FSMs on the first chip.

Example 2: the apparatus of Example 1, wherein the FSMs are to test each transmit lane of the set of transmit lanes, wherein two or more of the plurality of clusters are tested in parallel.

Example 3: the apparatus of Example 2, wherein the testing detects inter cluster defects and intra cluster defects.

Example 4: the apparatus of Examples 1-3, wherein the FSMs are to apply a first periodic signal to the transmit lanes under test, and apply a second periodic signal to the other transmit lanes of the sets of transmit lanes, and wherein a phase of the first periodic signal is opposite to a phase of the second periodic signal.

Example 5: the apparatus of Examples 1-4, wherein a test of each transmit lane of the sets of transmit lanes is part of a sort test of the first chip.

Example 6: the apparatus of Examples 1-5, wherein the individual ones of the plurality of FSMs comprise a transmit comparator, a transmit error register, and a transmit error analyzer.

Example 7: the apparatus of Example 6, wherein the transmit comparator is to identify one or more defective transmit lanes in the sets of transmit lanes, wherein to identify the one or more defective transmit lanes, the first comparator is to compare a signal detected on the transmit lane under test to an expected response provided by the global transmit expected response generator.

Example 8: the apparatus of Example 7, further comprising: a set of branch lanes to couple the transmit lanes to the FSMs.

Example 9: the apparatus of Examples 1-8, wherein each transmit lane of the sets of transmit lanes is coupled to a respective micro bump of the first chip, and each respective micro bump of the first chip is attached to a respective micro bump of a second chip.

Example 10: the apparatus of Examples 1-9, further comprising: a plurality of receive clusters on the first chip, wherein individual ones of the plurality of receive clusters comprise a set of receives lanes on the first chip; a plurality of second FSMs on the first chip, wherein individual ones of the plurality of receive clusters comprise one of the plurality of second FSMs; and a global receiver test generator communicatively coupled to each of the set of receive lanes on the first chip; and a global receiver expected response generator communicatively coupled to each of the plurality of second FSMs on the first chip.

Example 11: a multi-die module, comprising: a first die, comprising: a plurality of first transmit clusters and first receive clusters, wherein first sets of transmit lanes are in the first transmit clusters and first sets of receive lanes are in the first receive clusters; first finite state machines (FSMs), wherein one first FSM is provided in each of the first transmit clusters; second FSMs, wherein one second FSM is provided in each of the first receive clusters; a first global transmit test generator coupled to the first sets of transmit lanes; a first global transmit expected response generator coupled to the first FSMs; a first global receive test generator coupled to the first sets of receive lanes; and a first global receive expected response generator coupled to the second FSMs; and a second die coupled to the first die, wherein the second die comprises: a plurality of second transmit clusters and second receive clusters, wherein second sets of transmit lanes are in the second transmit clusters and second sets of receive lanes are in the second receive clusters; third FSMs, wherein one third FSM is provided in each of the second transmit clusters; fourth FSMs, wherein one fourth FSM is provided in each of the second receive clusters; a second global transmit test generator coupled to the second sets of transmit lanes; a second global transmit expected response generator coupled to the third FSMs; a second global receive test generator coupled to the second sets of receive lanes; and a second global receive expected response generator coupled to the fourth FSMs.

Example 12: the multi-die module of Example 11, wherein the second die is over the first die.

Example 13: the multi-die module of Example 12, further comprising: a third die between the first die and the second die.

Example 14: the multi-die module of Examples 11-13, wherein the second die is adjacent to the first die.

Example 15: the multi-die module of Examples 11-14, wherein the first sets of transmit lanes are coupled to the second sets of receive lanes by first micro bumps, and wherein the second sets of transmits lanes are coupled to the first sets of receives lanes by second micro bumps.

Example 16: the multi-die module of Examples 11-15, wherein the first set of transmit lanes comprises: signal lanes; redundant lanes; and a clock lane.

Example 17: the multi-die module of Examples 11-16, wherein the first FSMs, the second FSMs, the third FSMs, and the fourth FSMs each comprise a comparator, an error register, and an error analyzer.

Example 18: an electronic system, comprising: a board; a package substrate coupled to the board; a first die coupled to the package substrate, wherein the first die comprises a first test and repair architecture that uses a first global transmit test generator, a first global transmit expected response generator, a first global receive test generator, and a first global receive expected response generator; and a second die coupled to the first die, wherein the second die comprises a second test and repair architecture that uses a second global transmit test generator, a second global transmit expected response generator, a second global receive test generator, and a second global receive expected response generator.

Example 19: the electronic system of Example 18, wherein the first test and repair architecture and the second test and repair architecture enable sort testing and class testing.

Example 20: the electronic system of Example 18 or Example 19, wherein the electronic system is part of a personal computer, a server, a mobile device, a tablet, or an automobile.

What is claimed is:

1. An apparatus, comprising:
a plurality of transmit clusters on a first chip, wherein individual ones of the plurality of transmit clusters comprise a set of transmit lanes on the first chip;
a plurality of finite state machines (FSMs) on the first chip, wherein individual ones of the plurality of transmit clusters comprise one of the plurality of FSMs;
a global transmit test generator communicatively coupled to each of the set of transmit lanes on the first chip; and
a global transmit expected response generator communicatively coupled to each of the plurality of FSMs on the first chip.

2. The apparatus of claim 1, wherein the FSMs are to test each transmit lane of the set of transmit lanes, wherein two or more of the plurality of clusters are tested in parallel.

3. The apparatus of claim 2, wherein the testing detects inter cluster defects and intra cluster defects.

4. The apparatus of claim 1, wherein the FSMs are to apply a first periodic signal to the transmit lanes under test, and apply a second periodic signal to the other transmit lanes of the sets of transmit lanes, and wherein a phase of the first periodic signal is opposite to a phase of the second periodic signal.

5. The apparatus of claim 1, wherein a test of each transmit lane of the sets of transmit lanes is part of a sort test of the first chip.

6. The apparatus of claim 1, wherein the individual ones of the plurality of FSMs comprise a transmit comparator, a transmit error register, and a transmit error analyzer.

7. The apparatus of claim 6, wherein the transmit comparator is to identify one or more defective transmit lanes in the sets of transmit lanes, wherein to identify the one or more defective transmit lanes, the first comparator is to compare a signal detected on the transmit lane under test to an expected response provided by the global transmit expected response generator.

8. The apparatus of claim 7, further comprising:
a set of branch lanes to couple the transmit lanes to the FSMs.

9. The apparatus of claim 1, wherein each transmit lane of the sets of transmit lanes is coupled to a respective micro bump of the first chip, and each respective micro bump of the first chip is attached to a respective micro bump of a second chip.

10. The apparatus of claim 1, further comprising:
a plurality of receive clusters on the first chip, wherein individual ones of the plurality of receive clusters comprise a set of receives lanes on the first chip;
a plurality of second FSMs on the first chip, wherein individual ones of the plurality of receive clusters comprise one of the plurality of second FSMs; and
a global receiver test generator communicatively coupled to each of the set of receive lanes on the first chip; and
a global receiver expected response generator communicatively coupled to each of the plurality of second FSMs on the first chip.

11. A multi-die module, comprising:
a first die, comprising:
a plurality of first transmit clusters and first receive clusters, wherein first sets of transmit lanes are in the first transmit clusters and first sets of receive lanes are in the first receive clusters;
first finite state machines (FSMs), wherein one first FSM is provided in each of the first transmit clusters;
second FSMs, wherein one second FSM is provided in each of the first receive clusters;
a first global transmit test generator coupled to the first sets of transmit lanes;
a first global transmit expected response generator coupled to the first FSMs;
a first global receive test generator coupled to the first sets of receive lanes; and
a first global receive expected response generator coupled to the second FSMs; and
a second die coupled to the first die, wherein the second die comprises:
a plurality of second transmit clusters and second receive clusters, wherein second sets of transmit lanes are in the second transmit clusters and second sets of receive lanes are in the second receive clusters;
third FSMs, wherein one third FSM is provided in each of the second transmit clusters;
fourth FSMs, wherein one fourth FSM is provided in each of the second receive clusters;
a second global transmit test generator coupled to the second sets of transmit lanes;
a second global transmit expected response generator coupled to the third FSMs;
a second global receive test generator coupled to the second sets of receive lanes; and
a second global receive expected response generator coupled to the fourth FSMs.

12. The multi-die module of claim 11, wherein the second die is over the first die.

13. The multi-die module of claim 12, further comprising:
a third die between the first die and the second die.

14. The multi-die module of claim 11, wherein the second die is adjacent to the first die.

15. The multi-die module of claim 11, wherein the first sets of transmit lanes are coupled to the second sets of receive lanes by first micro bumps, and wherein the second sets of transmits lanes are coupled to the first sets of receives lanes by second micro bumps.

16. The multi-die module of claim 11, wherein the first set of transmit lanes comprises:
signal lanes;
redundant lanes; and
a clock lane.

17. The multi-die module of claim 11, wherein the first FSMs, the second FSMs, the third FSMs, and the fourth FSMs each comprise a comparator, an error register, and an error analyzer.

18. An electronic system, comprising:
a board;
a package substrate coupled to the board;
a first die coupled to the package substrate, wherein the first die comprises a first test and repair architecture that uses a first global transmit test generator, a first global transmit expected response generator, a first global receive test generator, and a first global receive expected response generator; and
a second die coupled to the first die, wherein the second die comprises a second test and repair architecture that uses a second global transmit test generator, a second global transmit expected response generator, a second global receive test generator, and a second global receive expected response generator.

19. The electronic system of claim 18, wherein the first test and repair architecture and the second test and repair architecture enable sort testing and class testing.

20. The electronic system of claim 18, wherein the electronic system is part of a personal computer, a server, a mobile device, a tablet, or an automobile.
